(19) United States
(12) Patent Application Publication
(10) Pub. No.: US 2008/0224125 A1
(43) Pub. Date: Sep. 18, 2008

(54) Semiconductor Device

(75) Inventors: Takahisa Tanabe, Saitama (JP); Masami Tsuchida, Saitama (JP)

Correspondence Address: SUGHRUE MION, PLLC, 2100 PENNSYLVANIA AVENUE, N.W., SUITE 800, WASHINGTON, DC, 20037, US

(73) Assignee: Pioneer Corporation (TMK), Tokyo (JP)

(21) Appl. No.: 11/632,293

(22) PCT Filed: Jun. 23, 2005
(86) PCT No.: PCT/JP2005/011556

§ 371 Date: Dec. 18, 2007

(30) Foreign Application Priority Data
Jul. 12, 2004 (JP) 2004-204058

(51) Int. Cl. H01L 51/00

(52) U.S. Cl. 257/40; 257/E51.001

(57) ABSTRACT

The disclosed is a semiconductor device which comprises a circuit which is formed on a substrate and which includes an insulated gate type semiconductor field-effect transistor element or an TFT element, wherein as compared with the electrostatic capacitance per a unit area of a gate insulating film at a channel part of the transistor element, the electrostatic capacitance per a unit area of a insulating film at the other portion of overlap part between electrodes or wiring lines is small. In the semiconductor device which has an insulated gate type semiconductor field-effect transistor element or a TFT element, a high mutual conductance is obtained and the absolute value of gate threshold voltage is repressed while the adverse influence to the circuit operation by means of the parasitic capacity is repressed.

### TECHNICAL FIELD

This technology relates to a semiconductor device in which an insulated gate type semiconductor field-effect transistor such as thin-film transistor (TFT) and so on, i.e., MIS (Metal-Insulator-Semiconductor) FET (Field Effect Transistor), is provided on a base member, particularly, relates to a semiconductor device which contains a thin-film transistor used an organic semiconductor (organic TFT) and so on.

### BACKGROUND ARTS

In recent years, the circuit technology which uses an organic semiconductor thin-film transistor (organic TFT) has been aimed at.

The coating apparatus, the vacuum deposition apparatus which are used for manufacturing such organic TFT are inexpensive as compared with the CVD apparatus, the spattering apparatus, etc., which are used for manufacturing generic inorganic TFT, for instance, amorphous silicon TFT. Further, the film-forming temperature to be used for the former TFT is lower than that of the latter one, and the maintenance of the apparatuses for the former ones is also easy. Therefore, it is possible to provide the organic TFT at a low cost as compared with the inorganic TFT and to look forward to apply the organic TFT to a flexible substrate such as plastics and so on.

For example, therefore, as for the circuitry device which utilizes the organic semiconductor as represented by organic TFT, use for various semiconductor devices including displays such as the organic electro-luminescent display, electronic tags, smart cards and so on with is reviewed.

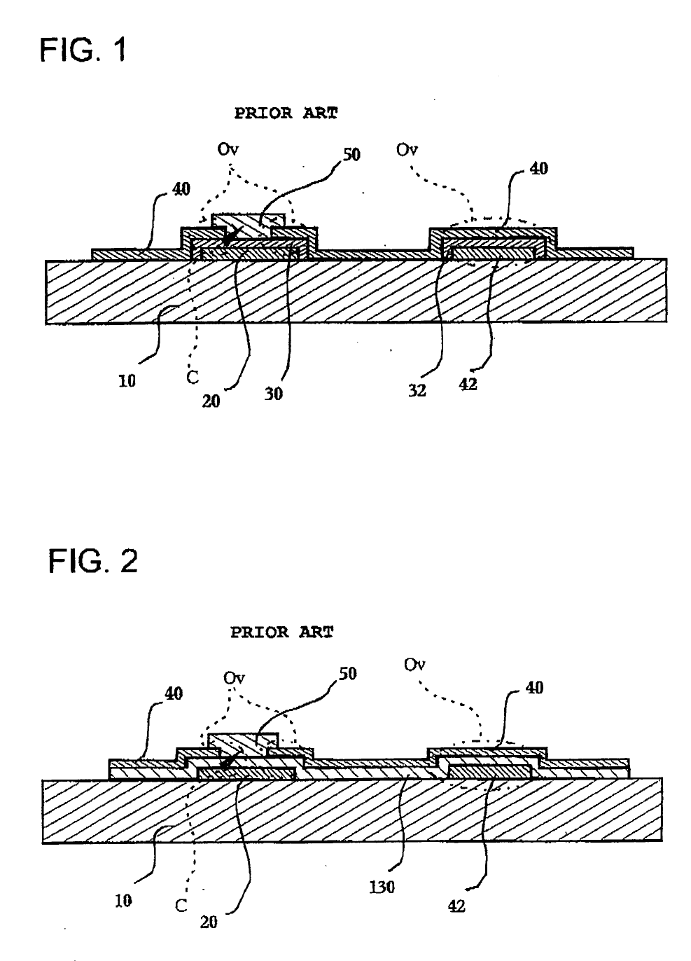

For instance, as shown in FIG. 1, the TFT may have a constitution wherein a gate electrode 20 is formed on an insulating substrate 10 such as glass or the like, an insulating film 30 (gate insulating film) is covered over the gate electrode, a second wiring line 40 which is patterned is formed over the insulating film in order to form a source electrode and a drain electrode, and a semiconductor layer 50 is formed at the gap (channel part) between the electrodes. By changing the voltage to apply to the gate electrode, the amount of electric charge at the phase boundary of the gate insulating film and the organic semiconductor layer is made to be surplus or lacking, in order to change the current (drain current Id) which flows among source electrode/organic semiconductor/drain electrode, for performing switching.

Incidentally, at the semiconductor device which has the TFT device of the above mentioned constitution, the other circuit wiring exists, and in the mutual overlap part of these circuit wirings, the insulation is performed by intervening an insulating film 30 between them. For instance, in FIG. 1, a first wiring line 42 is formed on the substrate at the side of the TFT element of above mentioned construction in addition to the second wiring line which forms the source and drain electrodes. The upper part of the wiring line 42 is surrounded by an insulating film 32, and the wiring line 40 is placed on the insulating film 32.

In the semiconductor device which has such TFT element or MISFET element, according to the so-called “scaling law” in the manufacturing thereof, fine patterning has been accelerated day to day. However, with decreasing the size of the transistor element, problems such as the increment of delay time of the element and increment of power consumption which are owing to the enlargement of the parasitic capacity and the parasitic resistance becomes remarkable.

In the non-patent literature 1, it was reported that the gate threshold voltage can be reduced by using the material of high dielectric constant for the gate insulating film.

In the semiconductor device which has the construction as shown in FIG. 1, when the insulating film 30 which covers the gate electrode 20 and the insulating film 32 which covers the first wiring line 42 is covered with a single layer of an insulating material having a high dielectric constant, it is possible to attain the reduction in the absolute value of the gate threshold voltage because a high mutual conductance is obtained. However, on the one hand, the parasitic capacity which is caused at the overlap part of the upper and lower electrodes or wirings becomes large.

FIG. 2 shows a configuration example of another semiconductor device in the prior art. In this example, a gate electrode 20 and a first wiring line 42 is formed on an insulating substrate 20, then, an insulating film 130 is formed so as to cover the whole upper part thereof. A second wiring line 40 which is patterned is formed over the insulating film in order to form a source electrode and a drain electrode, and a semiconductor layer 50 is formed at the gap (channel part) between the electrodes. In this construction, since the insulating film 130 is a single layer which is made of a single layer of the insulating material having high dielectric constant, the parasitic capacity between the electrodes becomes small, whereas the absolute value of the gate threshold voltage becomes large.

(Non-patent literature 1) Y. Lino et al. “Organic Thin-Film Transistor on a Plastic Substrate with Anodically Oxidized High-Dielectric-Constant Insulators” Japanese Journal of Applied Physics, Vol. 42, 299-304 (January 2003)

### DISCLOSURE OF THE INVENTION

### Problem to be Solved by the Invention

As mentioned above, in the constitution of the semiconductor device as shown in FIG. 1, since the parasitic capacity which is caused at the overlap part of the upper and lower electrodes becomes large, the adverse influence such as the delay in the circuit operation should be risen. In the constitution of the semiconductor device as shown in FIG. 2, the mutual conductance of transistor becomes small, and the absolute value of the gate threshold voltage becomes large. In the past, as for the dielectric constant of the insulating film, the characteristics of the transistor and the problem of the parasitic capacity in the transistor were in a mutually contradictory relationship and thus it is difficult to satisfy both conditions.

Therefore, this technology aims to provide an improved semiconductor device which solves the problems in the prior art's technology as mentioned above in the semiconductor device which has MISFET element or TFT element on the substrate. Further, this technology also aims to provide a semiconductor device which can reduce the absolute value of gate threshold voltage on the basis of obtaining a high mutual conductance while the adverse influence to the circuit operation by means of the parasitic capacity is repressed.

### Means for Solving a Problem

The technology which can solve the above problem is a semiconductor device which comprises a circuit which is formed on a substrate and which includes an insulated gate type semiconductor field-effect transistor element, wherein as compared with the electrostatic capacitance per a unit area of a gate insulating film at a channel part of the transistor element, the electrostatic capacitance per a unit area of a insulating film at the other portion of overlap part between electrodes or wiring lines is small.

The technology which can solve the above problem is a semiconductor device which comprises a circuit which is formed on a substrate and which includes an thin film transistor element, wherein as compared with the electrostatic capacitance per a unit area of a gate insulating film at a channel part of the transistor element, the electrostatic capacitance per a unit area of a insulating film at the other portion of overlap part between a lower electrode and an upper electrode is small.

Further, the above mentioned semiconductor device wherein the semiconductor of the thin-film transistor element is an organic semiconductor is disclosed.

Moreover, the above mentioned semiconductor device wherein the semiconductor of the thin-film transistor element is a silicon semiconductor is disclosed.

Further, the above mentioned semiconductor device wherein the insulating film at the portion other than the channel part of the transistor element has a layered structure of two or more kinds of materials which are different each other in the dielectric constant is disclosed.

Further, the above mentioned semiconductor device wherein the material which composes the gate insulating film at the channel part of the transistor element is a material which has the highest dielectric constant among the materials for insulating films at the portion other than the channel part is disclosed.

Further, the above mentioned semiconductor device wherein the thickness of the gate insulating film at the channel part of the transistor element is smaller than the thickness of the insulating film at the portion other than the channel part is disclosed.

Further, the above mentioned semiconductor device wherein dielectric constant of material which composes the gate insulating film at the channel part of the transistor element is larger than dielectric constant of material which composes the insulating film at the portion other than the channel part is disclosed.

Further, the above mentioned semiconductor device wherein the gate insulating film at the channel part of the transistor element is composed of a metal oxide is disclosed.

Further, the above mentioned semiconductor device wherein the gate insulating film at the channel part of the transistor element is composed of tantalum pentoxide is disclosed.

### BRIEF EXPLANATION OF THE DRAWINGS

(FIG. 1) is a schematic sectional view which shows the constitution in an example of the conventional semiconductor device.

(FIG. 2) is a schematic sectional view which shows the constitution in another example of the conventional semiconductor device.

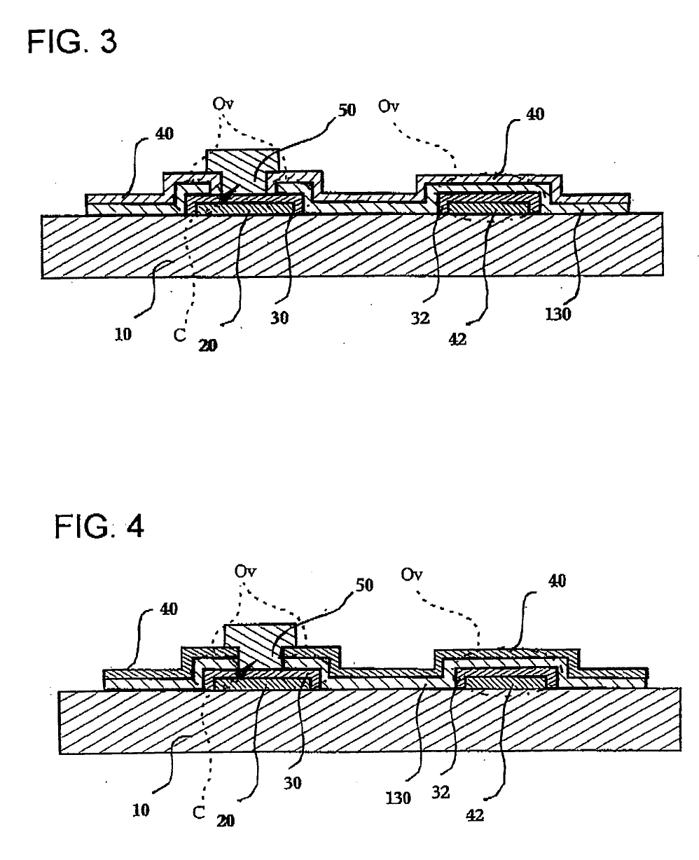

(FIG. 3) is a schematic sectional view which shows the constitution in an example of the semiconductor device according to the present technology.

(FIG. 4) is a schematic sectional view which shows the constitution in another example of the semiconductor device according to the present technology.

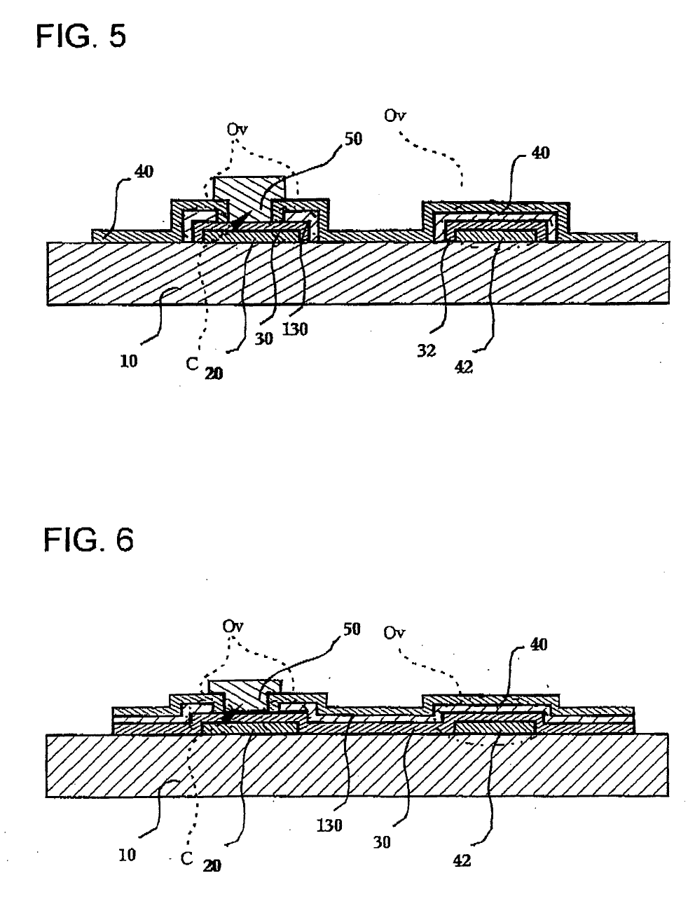

(FIG. 5) is a schematic sectional view which shows the constitution in still another example of the semiconductor device according to the present technology.

(FIG. 6) is a schematic sectional view which shows the constitution in still another example of the semiconductor device according to the present technology.

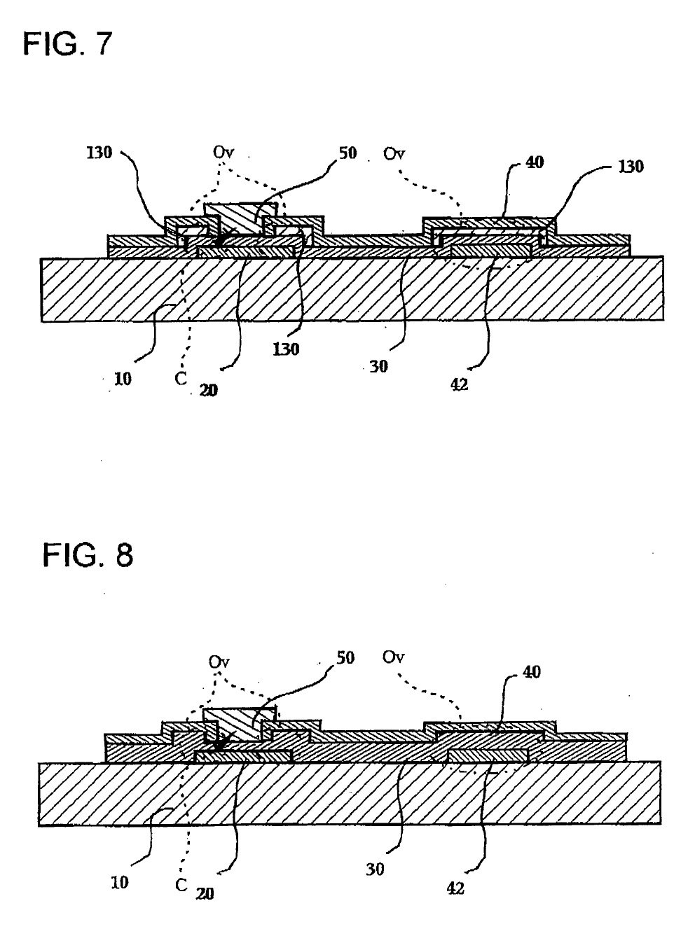

(FIG. 7) is a schematic sectional view which shows the constitution in still another example of the semiconductor device according to the present technology.

(FIG. 8) is a schematic sectional view which shows the constitution in still another example of the semiconductor device according to the present technology.

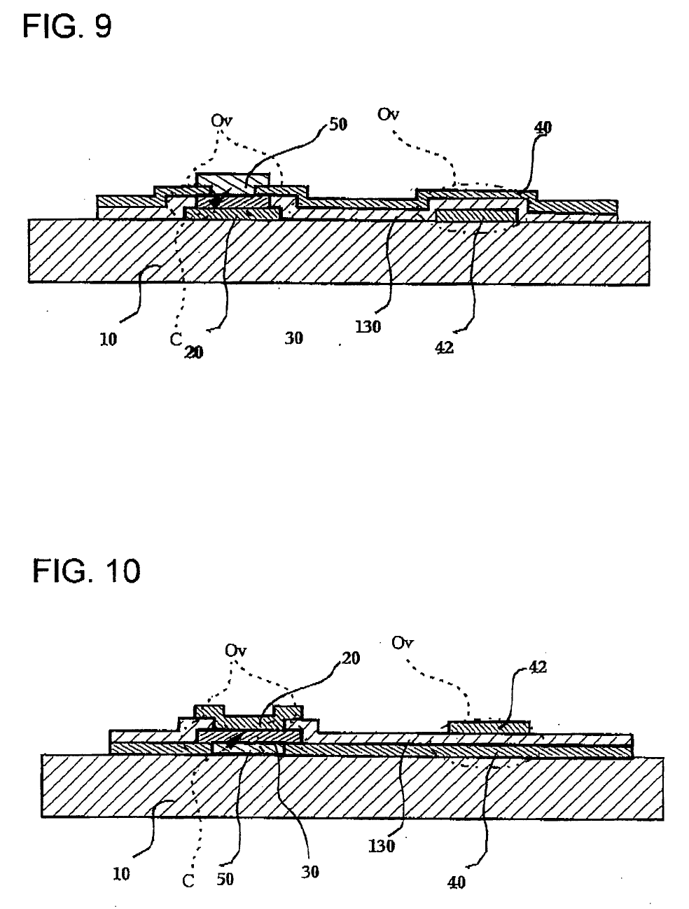

(FIG. 9) is a schematic sectional view which shows the constitution in still another example of the semiconductor device according to the present technology.

(FIG. 10) is a schematic sectional view which shows the constitution in still another example of the semiconductor device according to the present technology.

### EXPLANATION OF NUMERALS

10 Substrate material
20 gate electrode
30,32 Insulating film of high dielectric constant
40,42 Wiring line
50 Semiconductor layer
52 Organic luminous layer
130 Insulating film of low dielectric constant
C Channel part of transistor device
Ov Overlap part of electrodes or wiring lines

### BEST MODE FOR CARRYING OUT THE INVENTION

Hereinafter, the semiconductor device according to the present technology will be specifically described based on embodiments shown in FIGS. 3-10. Incidentally, in FIGS. 3-10, thickness of each part is drawn with exaggeration.

As mentioned above, the present technology is on a semiconductor device which comprises a circuit which is formed on a substrate and which includes an MISFET element or an TFT element, wherein as compared with the electrostatic capacitance per a unit area of a gate insulating film at a channel part of the transistor element, the electrostatic capacitance per a unit area of a insulating film at the other portion of overlap part between electrodes or wiring lines is set to be small.

Incidentally, in this specification, the “channel part” of the transistor denotes the conductive pathway section which connects electrically between source and drain electrodes at the upper site (or lower site) of the existence position of the gate electrode in a section along the direction of the thickness of the field-effect transistor, namely, the section which excludes the overlap part between the gate electrode and the source/drain electrodes, and it is the minimum part which is needed for working as the transistor.

Thus, in this technology, the electrostatic capacitance per a unit area of the insulating film located at the channel part of the transistor element is made to differ from the electrostatic capacitance per a unit area of a insulating film at the other portion of overlap part between electrodes, and only the channel part is made to have a large electrostatic capacitance. At the channel part, because the electrostatic capacitance per a unit area of the gate insulating film is large, it is possible to gain a high mutual conductance as being proportional to the high electrostatic capacitance, and thus it is possible to reduce the absolute value of the gate threshold voltage. With respect to the other portion of the overlap part between electrodes, because the electrostatic capacitance per a unit area is small, the parasitic capacity at the portion does not become large, and thus the adverse influence to the transistor circuit operation can be repressed at a low level.

In the present technology, as for the technique to make the electrostatic capacitance of the insulating film at the channel part to be different from the electrostatic capacitance of the other overlap part of the electrodes, there is not a specific limitation. For instance, as described below in detail, it is possible to be accomplished by using as the insulating film two or more materials which are different from each other in the dielectric constant, or by setting the thicknesses of insulating film at the respective positions to be different from each other, or by using the combination of these techniques.

FIG. 3 is a schematic sectional view which shows the constitution in an embodiment of the semiconductor device according to the present technology. In this embodiment, as shown in FIG. 3, on an insulating substrate 10, a gate electrode 20 and a first wiring line 42 is formed. Then, an insulating film of a high dielectric constant 30 is layered over the gate electrode 20 and the first wiring line 42 so as to cover them. Further, a insulating film of a low dielectric constant 130 is layered approximately all over the circuit part of the substrate which includes the upper part of the gate electrode 20 and the upper part of the first wiring line 42 which has been covered with the insulating film of high dielectric constant 30, except for the channel part C over the gate electrode. At the channel part C over the gate electrode, the insulating film of low dielectric constant 130 is not stacked, and thus as the insulating film at this position, there is a single layer of the insulating film of high dielectric constant 30. Further, a second wiring line 40 which includes source and drain electrodes of the TFT is stacked so as to just cover the insulating film of low dielectric constant 130. On the channel part C over the gate electrode 20 where the above mentioned insulating film of low dielectric constant 130 and the second wiring line 40 are not stacked, a semiconductor layer 50 is stacked so as to form a TFT element. Incidentally, such a layered constitution can be formed by appropriately using the known masking technologies, the known photo lithography and etching technologies when or after the respective layers are layered, for instance.

In the semiconductor device of the embodiment shown in FIG. 3, since the gate insulating film at the channel part C of the TFT consists of a single layer of the insulating film of high dielectric constant 30, it is possible to gain a high mutual conductance, and also possible to reduce the absolute value of the gate threshold voltage.

Now, this point will be described in detail. First, the mutual conductance gₘ can be found by the following formula.

$$gm = \frac{\partial {I}_{D}}{\partial {V}_{GS}} \vert {V}_{DS} = const . \qquad ( Numerical formula 1 )$$

Further, the gₘ in a saturated area can be found by the following formula.

$$gm = \frac{W}{L} μ C ( {v}_{GS} - {V}_{th} ) \qquad ( Numerical formula 2 )$$

W: Channel width of TFT
L: Channel length of TFT
μ: Mobility of semiconductor
C: Electrostatic capacitance per a unit area of gate insulating film
VGS: Voltage between gate and source
Vth: Gate threshold voltage

Therefore, the mutual conductance is proportional to the electrostatic capacitance per unit area of the gate insulating film. As shown in the following formula, the electrostatic capacitance is inversely proportional to the film thickness and is proportional to the dielectric constant of the insulating film material. Therefore, the mutual conductance is proportional to the dielectric constant of the gate insulating film.

C=∈₀∈ᵢ/t (Numerical Formula 3)

∈₀: Dielectric constant of the vacuum
∈ᵢ: Relative dielectric constant of the insulating film
t: Film thickness of the insulating film

As for the film thickness of the insulating film, the film thinning may encounter a certain limit as far as the reliability, uniformity, etc., of the film to be obtained are in satisfied levels. Thus, in order to improve the mutual conductance, to use the material of high dielectric constant for the gate insulating film as in the embodiment shown in FIG. 3 is effective. Also, the point that the absolute value of the gate threshold voltage can be reduced by using the material of high dielectric constant for the gate insulating film is shown in the non-patent literature 1 as mentioned above.

At the portion other than the channel part C of TFT, since the double layered structure of the insulating layer of high dielectric constant 30, 32 and the insulating layer of low dielectric constant 130 is constructed between the lower part which is the gate electrode 20 and the first wiring line 42 and the upper part which is the second wiring line 40 in the figure, the parasitic capacity between the upper and lower electrodes or the upper and lower wiring lines comes to be small as compared with the case that the insulation is performed only by a single insulating film of high dielectric constant. In addition, because the insulating film is two layered structure, the insulation characteristic between the electrodes or wiring lines can be also improved.

Each of FIGS. 4-7 is schematic sectional view which shows the constitution in mutually independent other embodiment of the semiconductor device according to the present technology. In the embodiments shown in FIGS. 4-7, like the one in the embodiment shown in FIG. 3, the gate insulating film at the channel part C of the TFT is formed with a single layer of the insulating film of high dielectric constant 30, and at the overlap part Ov of the gate electrode 10 and the second wiring line (source/drain electrodes) 40, and at the overlap part Ov of the first wiring line 42 and the second wiring line 40 the insulating layer is formed with two layers of the insulating film of high dielectric constant 30, 32 and the insulating film of low dielectric constant 130. Therefore, a high mutual conductance can be attained and it is also possible to reduce the absolute value of the gate threshold voltage, as in the case of the embodiment shown in FIG. 3. In addition, the parasitic capacity in the overlap parts can be also kept at a low level.

Incidentally, in the embodiment shown in FIG. 4, the edge structure of the source/drain electrodes of the TFT element which is formed by the second wiring line 40 is different from that of the embodiment shown in FIG. 3, as shown in the figures. At the channel part C, the second wiring line 40 which comes into contact with the semiconductor layer 50 is not formed at side faces of the insulating film of low dielectric constant 130, and the contact with the semiconductor layer 50 is enabled only over the upper part of the insulating film of low dielectric constant 130. Thus, the formation of the insulating film of low dielectric constant 130 and the formation of the second wiring line 40 can be proceeded continuously with using the identical mask, or can be done at the same time by simultaneous etching of these two layers.

In the embodiment shown in FIG. 5, the area for forming the insulating film of low dielectric constant 130 is different from that of the embodiment shown in FIG. 3, as shown in the figures. The area is kept substantially only at the overlap part Ov of the gate electrode 10 and the second wiring line (source/drain electrodes) 40, and the overlap part Ov of the first wiring line 42 and the second wiring line 40.

In the embodiment shown in FIG. 6, the area for forming the insulating film of high dielectric constant 30 is different from that of the embodiment shown in FIG. 3, as shown in the figures. The area is extended approximately all over the circuit part on the substrate.

In the embodiment shown in FIG. 7, the area for forming the insulating film of high dielectric constant 30 is different from that of the embodiment shown in FIG. 3, as shown in the figures. The area is extended approximately all over the circuit part on the substrate. Further, the area for forming the insulating film of low dielectric constant 130 is also different from that of the embodiment shown in FIG. 3. The area is kept substantially only at the overlap part Ov of the gate electrode 10 and the second wiring line (source/drain electrodes) 40, and the overlap part Ov of the first wiring line 42 and the second wiring line 40.

As the material for the high dielectric constant insulating film, for instance concretely, metal oxides such as tantalum pentoxide (Ta₂O₅), alumina (Al₂O₃), titanium oxide (TiO₂), zinc oxide (ZrO₂), lanthanum oxide (La₂O₃), hafnium oxide (HfO₂) and so on can be cited. Of course, the material is not limited thereto. Among them, tantalum pentoxide (Ta₂O₅) can be cited as a particularly preferable example.

As the material for the low dielectric constant insulating film, although it is varied by the kind of the material for the high dielectric constant insulating film to be used, for instance concretely, inorganic materials such as silicon oxide (SiO₂), silicon nitride (Si₃N₄) and so on; organic materials such as polyvinyl alcohol (PVA), polyvinyl phenol (PVP), cyanoethyl pullulan (CYEPL), polyacrylonitrile (PAN), polyarylene ether (PAE), benzo cyclobutene (BCB), perfluoro hydrocarbons, polyquinolines and so on; various inorganic or organic SOG materials; or various porous materials can be cited. Of course, the material is not limited thereto.

As the material for gate electrode, the first and second wirings, for example, metals such as tantalum, aluminum, chromium, zinc, molybdenum, iron, copper, silver, gold, titanium, palladium and so on, or alloys thereof, or multilayered structures thereof; metal oxides such as indium tin oxide (ITO), indium zinc oxide (IZO) and so on; and polymers such as polyaniline, PEDT/PSS and so on are suitable, although the material is not limited thereto.

As the material for the semiconductor layer, for example, organic semiconductors, and inorganic semiconductor such as amorphous silicon, polysilicon and so on are applicable. Particularly, when using an organic semiconductor, the constitution according to the present technology is effective. As the material of the organic semiconductor, various materials such as acene type low molecular weight compounds such as pentacene and so on, thiophene type oligomers such as 3-hexyl thiophene, or high molecular weight derivatives thereof are applicable.

Incidentally, although in the embodiments shown in FIGS. 3-7 the two layered structure of the high dielectric constant insulating film and the low dielectric insulating film is used, three or more layered structure of the high dielectric constant insulating film and the low dielectric insulating film, or three or more layered structure of three or more kinds of materials the dielectric constant of which are different mutually may be adaptable in the semiconductor device according to the present technology, as a matter of course.

FIG. 8 is a schematic sectional view which shows the constitution in a still other embodiment of the semiconductor device according to the present technology. In this embodiment, in contrast to the embodiments shown in FIGS. 3-8, not only the insulating film (gate insulating film) at the channel part C of TFT, but also the insulating film located at the overlap part Ov of the gate electrode 10 and the second wiring line (source/drain electrodes) 40, and the insulating film located at the overlap part Ov of the first wiring line 42 and the second wiring line 40 are formed with the insulating film of high dielectric constant 30 alone. Then, only at the channel part C of TFT, the thickness of the insulating film is set to be smaller than the thickness at other portion. As mentioned above, since the mutual conductance is proportional to the electrostatic capacitance per a unit area of the gate insulating film, and the electrostatic capacitance is inversely proportional to the film thickness, it is possible to attain the desired characteristic by differentiating the film thickness at the channel part from that of the other portion.

Incidentally, when the thickness only at the channel part C is set to be smaller than the thickness at other portion, for example, it is possible to utilize a technique where until a certain thickness the insulating film is deposited at the channel part C in the same fashion as being at the other portion, and then a mask is applied only at the channel part and the deposition of the insulating film at other portion is continued until the thickness at other portion reaches a prescribed thicker thickness. Alternatively, a technique where first the thicker thickness of the insulating film is deposited over the whole area, and then only at the cannel part the formed insulating film is dug down to a prescribed thickness by etching or the like is also applicable.

As the high dielectric constant material which can be used in this embodiment, the same materials as shown in the above embodiments of FIGS. 3-8 can be used. With respect to the other materials, the same as mentioned above can be used, too.

FIG. 9 is a schematic sectional view which shows the constitution in a still other embodiment of the semiconductor device according to the present technology. In this embodiment, although the insulating film of high dielectric constant 30 and the insulating film of low dielectric constant 130 are used as in the cases of embodiments shown in FIGS. 3-8, but in contrast to the embodiments shown in FIGS. 3-8, the insulating film of high dielectric constant 30 and the insulating film of low dielectric constant 130 do not overlap each other even at the overlap part Ov of the gate electrode 10 and the second wiring line (source/drain electrodes) 40, and the overlap part Ov of the first wiring line 42 and the second wiring line 40. At the channel part C of TFT, the insulating film is formed with a single layer of the insulating film of high dielectric constant 30, and at the other part, the insulating film is formed with a single layer of the insulating film of low dielectric constant 130, respectively. Such a structure can be manufactured by an operation where first one layer is formed in a prescribed shape, and then the other layer is deposited while a mask is applied to the firstly formed layer. As compared with the embodiment shown in FIGS. 3-8, although the number of the manufacturing steps becomes slightly larger, but it is possible to provide a thinner circuit formation because in each part the insulating film is a single layer.

As the high dielectric constant material and the low dielectric constant material which can be used in this embodiment, the same materials as exemplified above in relation to the embodiments shown in FIGS. 3-8 can be used, for example. As for the ratio of the dielectric constant of the low dielectric constant material to the dielectric constant of the high dielectric constant material, the approximately same rate as the aforementioned one can be applicable. Further, with respect to the other materials, the same as mentioned above can be also used.

FIG. 10 is a schematic sectional view which shows the constitution in a still other embodiment of the semiconductor device according to the present technology. In this embodiment, the TFT element part formed on the substrate is different from those of the embodiments shown in FIGS. 3-9. The source/drain electrodes (the second wiring line 40) are laid near the substrate 10, as compared with the gate electrode 20. Namely, in this embodiment, on the insulating substrate 10 the semiconductor layer 50 is formed, and the second wiring line 40 which constitutes the source/drain electrodes is provided so as to come into contact with the semiconductor layer, and then at the upper region of the semiconductor layer 50 the insulating film of high dielectric constant 30 which constitutes the gate insulating film is layered on. Onto the upper part of the wiring line 40 except the portion where the semiconductor layer has been formed, the insulating film of low dielectric constant 130 is layered. In order that the insulating film of high dielectric constant 30 can show a single layer only at the just upper portion of the semiconductor layer 50, namely, only at the channel part C of TFT, the insulating film of low dielectric constant 130 overlays partially on the insulating film of high dielectric constant 30 at the both side edge portions. At the portion where the insulating film of high dielectric constant 30 is kept as the single layer, the gate electrode 20 is layered on.

In case of this embodiment, like the cases of the embodiments shown in FIGS. 3-7, the gate insulating film at the channel part C of TFT is formed only by a single layer of the high dielectric constant insulating film 30. Therefore, a high mutual conductance can be attained and it is also possible to reduce the absolute value of the gate threshold voltage. With respect to the portion other than the channel part C of TFT, since the double layered structure of the insulating layer of high dielectric constant 30 and the insulating layer of low dielectric constant 130 is constructed at the overlap portion of electrodes or wiring lines, the parasitic capacity between the electrodes or wiring lines becomes small In addition, because the insulating film is two layered structure, the insulation characteristic between the electrodes or wiring lines can be also improved.

As the high dielectric constant material and the low dielectric constant material which can be used in this embodiment, the same materials as exemplified above in relation to the embodiments shown in FIGS. 3-8 can be used, for example. As for the ratio of the dielectric constant of the low dielectric constant material to the dielectric constant of the high dielectric constant material, the approximately same rate as the aforementioned one can be applicable. Further, with respect to the other materials, the same as mentioned above can be also used.

Incidentally, the semiconductor device according to the present technology has been described as above by exemplifying the cases of the semiconductor device which has a TFT element on the insulating substrate. However, in the cases of the semiconductor device which has a MISFET element other than TFT on the insulating substrate, for instance, by applying the similar construction with those in the embodiments shown in FIGS. 3-10, it is possible that the electrostatic capacitance per a unit area of the gate insulating film at the channel part of the transistor element is set to be larger than the electrostatic capacitance per a unit area of the insulating film at the other portion of overlap part between electrodes or wiring lines. Further, in the embodiments shown in FIGS. 3-10, the constitution of the transistor device, the constitution of the wiring line, etc., are represented as simplified ones, for the purpose of simplification. However, the constitution of the semiconductor device according to the present technology is not limited to such embodied ones. For instance, the transistor element can be provided with an additional protective layer, a sealing package, and so on, and it can have one of various patterns of the wiring construction or an additional layered wiring construction.

Further, in the manufacturing of the semiconductor device according to the present technology, the formation of each layer and the patterning thereof can be proceeded by using the known technologies. For example, in the formation of the organic layers such as the organic semiconductor layer and so on, the coating methods such as spin coating, vacuum deposition method, etc., are utilizable. As for the inorganic insulating film or the like, the plasma CVD method, etc., are utilizable. As for the metal film, tin oxide, indium oxide, ITO, or the like, the spattering method, vacuum deposition method, etc., are utilizable. In the patterning of the layers, a combination of known photo lithography and known dry etching or wet etching, as well as the patterning of using electron beam can be used.

1-10. (canceled)

11. Semiconductor device which comprises a circuit which is formed on a substrate and which includes an insulated gate type semiconductor field-effect transistor element, wherein as compared with the electrostatic capacitance per a unit area of a gate insulating film at a channel part of the transistor element, the electrostatic capacitance per a unit area of a insulating film at the other portion of overlap part between electrodes or wiring lines is small, and
wherein the material which composes the gate insulating film at the channel part of the transistor element is a material which has the highest dielectric constant among the materials for insulating films at the portion other than the channel part; or wherein dielectric constant of material which composes the gate insulating film at the channel part of the transistor element is larger than dielectric constant of material which composes the insulating film at the portion other than the channel part.

12. The semiconductor device according to claim 11, wherein the insulated gate type semiconductor field-effect transistor element is a thin film transistor element.

13. The semiconductor device according to claim 12, wherein the semiconductor of the thin-film transistor element is an organic semiconductor.

14. The semiconductor device according to claim 12, wherein the semiconductor of the thin-film transistor element is a silicon semiconductor.

15. The semiconductor device according to claim 11, wherein the insulating film at the portion other than the channel part of the transistor element has a layered structure of two or more kinds of materials which are different each other in the dielectric constant.

16. The semiconductor device according to claim 11, wherein the thickness of the gate insulating film at the channel part of the transistor element is smaller than the thickness of the insulating film at the portion other than the channel part.

17. The semiconductor device according to claim 11, wherein the gate insulating film at the channel part of the transistor element comprises an metal oxide.

18. The semiconductor device according to claim 11, wherein the gate insulating film at the channel part of the transistor element comprises tantalum pentoxide.
